(19) United States
(12) Patent Application Publication
(10) Pub. No.: US 2015/0325722 A1
(43) Pub. Date: Nov. 12, 2015

(54) LAYER SYSTEM FOR THIN-FILM SOLAR CELLS

(71) Applicant: Saint-Gobain Glass France, Courbevoie (FR)

(72) Inventors: Jörg PALM, München (DE); Stephan POHLNER, München (DE); Thomas HAPP, München (DE); Thomas DALIBOR, Herrsching am Ammersee (DE); Stefan JOST, München (DE); Roland DIETMÜLLER, München (DE)

(21) Appl. No.: 14/409,684

(22) PCT Filed: Jun. 19, 2013
(86) PCT No.: PCT/EP2013/062715

§ 371 Date: Dec. 19, 2014

(30) Foreign Application Priority Data
Jun. 20, 2012 (EP) 12172697.0

(51) Int. Cl. H01L 31/032; H01L 31/18

(52) U.S. Cl. CPC H01L 31/0324; H01L 31/18

(57) ABSTRACT

The present invention relates to a layer system (1) for thin-film solar cells (100) and solar modules, comprising
an absorber layer (4) that includes a chalcogenide compound semiconductor and
a buffer layer (5) that is arranged on the absorber layer (4) and includes halogen-enriched InₓS_{y} with ⅔≦x/y≦1,
   wherein the buffer layer (5) consists of a first layer region (5.1) adjoining the absorber layer (4) with a halogen mole fraction A₁ and a second layer region (5.2) adjoining the first layer region (5.1) with a halogen mole fraction A₂ and the ratio A₁/A₂ is ≧2 and the layer thickness (d₁) of the first layer region (5.1) is ≦50% of the layer thickness (d) of the buffer layer (5).

The present invention relates to a layer system for thin-film solar cells and a method for producing the layer system.

Thin-film systems for solar cells and solar modules are sufficiently known and available on the market in various designs depending on the substrate and the materials applied thereon. The materials are selected such that the incident solar spectrum is utilized to the maximum. Due to the physical properties and the technological handling qualities, thin-film systems with amorphous, micromorphous, or polycrystalline silicon, cadmium telluride (CdTe), gallium arsenide (GaAs), copper indium (gallium) selenide sulfide (Cu(In,Ga)(S,Se)₂), and copper zinc tin sulfoselenide (CZTS from the group of the kesterites) as well as organic semiconductors are particularly suited for solar cells. The pentenary semiconductor Cu(In,Ga)(S,Se)₂ belongs to the group of chalcopyrite semiconductors that are frequently referred to as CIS (copper indium diselenide or copper indium disulfide) or CIGS (copper indium gallium diselenide, copper indium gallium disulfide, or copper indium gallium disulfoselenide). In the abbreviation CIGS, S can represent selenium, sulfur, or a mixture of the two chalcogens.

Current thin-film solar cells and solar modules based on Cu(In,Ga)(S,Se)₂ require a buffer layer between a p-conductive Cu(In,Ga)(S,Se)₂ absorber and an n-conductive front electrode that usually comprises zinc oxide (ZnO). According to current knowledge, this buffer layer enables electronic adaptation between the absorber material and the front electrode. Moreover, it offers protection against sputtering damage in the subsequent process step of deposition of the front electrode by DC-magnetron sputtering. Additionally, by constructing a high-ohm intermediate layer between p- and n-semiconductors, it prevents current drain from electrically good zones into poor zones.

To date, cadmium sulfide (CdS) has been most frequently used as a buffer layer. To be able to produce good efficiency of the cells, CdS has, to date, been deposited in a chemical bath process (CBD process), a wet chemical process. However, associated with this is the disadvantage that the wet chemical process does not fit well into the process cycle of the current production of Cu(In,Ga)(S,Se)₂ thin-film solar cells.

A further disadvantage of the CdS-buffer layer consists in that it includes the toxic heavy metal cadmium. This creates higher production costs since increased safety precautions must be taken in the production process, e.g., in the disposal of wastewater. Moreover, additional costs arise at the time of disposal of the product after expiration of the service life of the solar cell.

Consequently, various alternatives to the buffer made of CdS have been tested for different absorbers from the family of the Cu(In,Ga)(S,Se)₂ semiconductors, e.g., sputtered ZnMgO, Zn(S,OH) deposited by CBD, In(O,OH) deposited by CBD, and indium sulfide deposited by ALD (atomic layer deposition), ILGAR (ion layer gas deposition), spray pyrolysis, or PVD (physical vapor deposition) processes, such as thermal deposition or sputtering.

However, these materials still are not suitable as buffers for solar cells based on Cu(In,Ga)(S,Se)₂ for commercial use, since they do not achieve the same efficiencies (ratio of incident power to the electrical power produced by a solar cell) as those with a CdS buffer layer. The efficiencies for such modules are roughly up to about 20% for lab cells on small surfaces and between 10% and 12% for large-area modules. Moreover, they present excessive instabilities, hysteresis effects, or degradations in efficiency when they are exposed to light, heat, and/or moisture.

A further disadvantage of CdS is based on the fact that CdS is a direct semiconductor with a direct electronic band gap of roughly 2.4 eV. Consequently, in a Cu(In,Ga)(S,Se)₂/CdS/ZnO solar cell, already with CdS-film thicknesses of a few 10 nm, the incident light is mostly absorbed. The light absorbed in the buffer layer is lost for the electrical yield since the charge carriers generated in this layer recombine right away since there are many crystal defects in this region of heterojunction and in the buffer material acting as recombination centers. Thus, the light absorbed in the buffer layer is lost for the electrical yield. As a result, the efficiency of the solar cell is reduced, which is disadvantageous for a thin-film cell.

A layer system with a buffer layer based on indium sulfide is, for example, known from WO 2009/141132 A2. The layer system comprises a chalcopyrite absorber of the CIS family, in particular Cu(In,Ga)(S,Se)₂ in conjunction with a buffer layer of indium sulfide. The indium sulfide (InᵥS_{w}) buffer layer has, for example, a slightly indium-rich composition with v/(v+w)=41% to 43% and can be deposited with various non-wet chemical methods, for example, by thermal deposition, ion layer gas reaction, cathode sputtering (sputtering), atomic layer deposition (ALD), or spray pyrolysis.

However, in the development to date of this layer system and of the production method, it has been demonstrated that the efficiency of solar cells with an indium sulfide buffer layer is lower than that with CdS buffer layers.

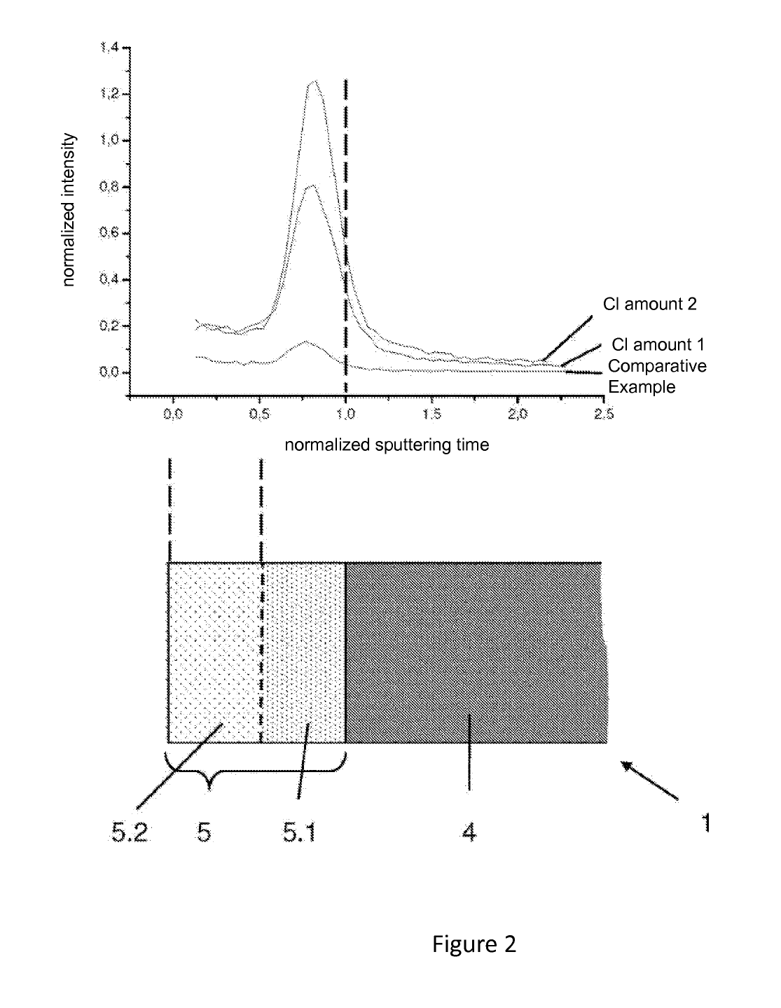

Emits et al.: “Characterization of ultrasonically sprayed InₓS_{y} buffer layers for Cu(In,Ga)Se₂ solar cells”, Thin Solid Films, Elsevier-Sequoia S. A. Lausanne, Vol. 515, No. 15, 27, Apr. 2007 (2007 Apr. 27), pp. 6051-6054, shows an indium sulfide buffer layer for a Cu(In,Ga)Se₂-solar cell. FIG. 2 of this document presents the chlorine content of the indium sulfide buffer layer. The measurement refers to a measurement structure where no absorber is present. The content of indium and sulfide is outside the range limits InₓS_{y} with ⅔≦x/y≦1.

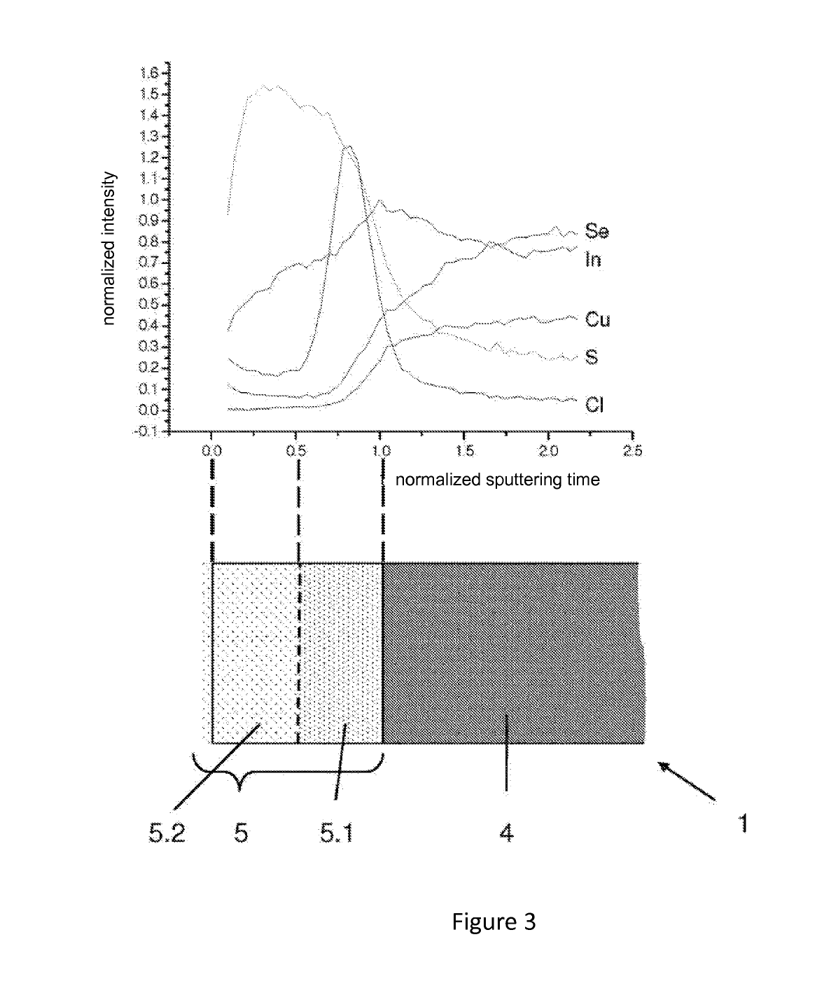

Bar et al.: “Deposition of In₂S₃ on Cu(In,Ga)(S,Se)₂ thin film solar cell absorbers by spray ion layer gas reaction: Evidence of strong interfacial diffusion”, Applied physics letters, AIP, American Institute of Physics, Melville, N.Y., US, Vol. 90, No. 13, 29. Mar. 2007, pp 132118-1-132118-3 shows an indium sulfide buffer layer on a Cu(In,Ga)(S,Se)₂— solar cell. FIG. 3 shows the surface composition of a test specimen, wherein the absorber is situated according to the cycle sequence on the left side of the diagram such that the chlorine signal increases away from the absorber and decreases toward the absorber.

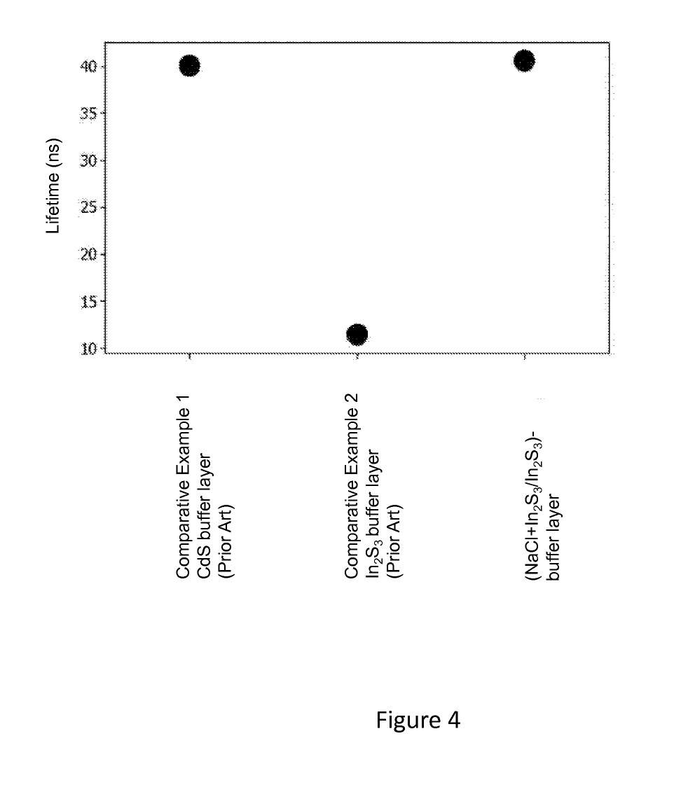

Axel Eicke, et al.: “Chemical characterization of evaporated In₂Sₓ buffer layers in Cu(In,Ga)Se₂ thin-film solar cells with SNMS and SIMS” shows indium sulfide buffer layers on a Cu(In,Ga)(S,Se)₂— solar cell. In FIG. 4, the concentration of various components is plotted against the sputtering time. Signals such as Cu, Se, and O refer to the absorber. The content of indium and sulfide is outside the range limits InₓS_{y} with ⅔≦x/y≦1.

Consequently, the object of the present invention is to provide a layer system based on a compound semiconductor with a buffer layer that has a high level of efficiency and high stability, with production that is economical and environmentally safe.

This object is accomplished according to the invention by a layer system according to claim 1. Advantageous improvements of the invention emerge from the subclaims.

The invention further includes a method for producing a layer system for thin-film solar cells.

A use of the layer system according to the invention is presented in further claims.

The layer system according to the invention for thin-film solar cells comprises at least
an absorber layer that includes a chalcogenide compound semiconductor and
a buffer layer that is arranged on the absorber layer and includes halogen-enriched InₓS_{y} with ⅔≦x/y≦1,
   wherein the buffer layer consists of a first layer region adjoining the absorber layer with a halogen mole fraction A₁ and a second layer region adjoining the first layer region with a halogen mole fraction A₂ and the ratio A₁/A₂ is ≧2.

Since the elements of the buffer layer can, in each case, be present in different oxidation states, all oxidation states are referred to in the following with the name of the element unless explicitly indicated otherwise. Consequently, the term sodium, for example, means elemental sodium and sodium ions as well as sodium in compounds. Moreover, the term halogen means elemental halogen and halide as well as halogen in compounds.

In an advantageous embodiment of the layer system according to the invention, the layer thickness d₁ of the first layer region is ≦50% of the layer thickness d the total buffer layer. The layer thickness d of the buffer layer is the sum of the layer thicknesses of the first layer region and of the second layer region. In a preferred embodiment, the layer thickness d₁ of the first layer region is ≦30% and particularly preferably ≦20% of the layer thickness d of the buffer layer. In a preferred embodiment, the layer thickness d₁ of the first layer region is 30% and particularly preferably 20% of the layer thickness d of the buffer layer.

The present invention is based on the finding of the inventors that enrichment of a halogen in the buffer layer at the interface with the absorber layer increases the open circuit voltage and, thus, the efficiency of a solar cell according to the invention. This can be explained by the fact that the halogen enrichment through the relatively large halogen atoms or halogen ions localized at the interface forms a diffusion barrier against the inward diffusion of impurities such as copper out of the absorber layer into the buffer layer. The halogen atoms can also have a positive effect both on the electronic band adaptation at the absorber-buffer heterojunction and on the recombination of the charge carriers at this interface. In order not to degrade the electronic properties of the buffer layer, the halogen enrichment should be limited in a narrow layer region of the buffer layer at the interface with the absorber layer.

A delta-peak-shaped halogen enrichment at the interface the absorber layer would, in principle, be adequate to obtain an improvement of the efficiency. However, because of the surface roughness of the absorber layer, a delta-peak-shaped halogen enrichment is neither producible nor verifiable by existing measurement methods. Fixing the layer thickness d₁ in the above-mentioned range has, consequently, proved particularly advantageous. A particularly economical method for introduction of the halogen that results in the halogen enrichment claimed has also been developed.

In another advantageous embodiment of a layer system according to the invention, the ratio of the halogen mole fractions A₁/A₂ is from 2 to 1000, preferably from 9 to 1000, in particular from 5 to 100, and particularly preferably from 10 to 100, in particular from 5 to 100. In this range, particularly good efficiencies can be obtained.

In an advantageous embodiment of the invention, the chalcogenide compound semiconductor of the absorber layer contains Cu(In,Ga,Al)(S,Se)₂ and preferably CuInSe₂, CuInS₂, Cu(In,Ga)Se₂ or Cu(In,Ga)(S,Se)₂, or Cu₂ZnSn(S,Se)₄. In another advantageous embodiment of the layer system according to the invention, the absorber layer consists substantially of the chalcogenide compound semiconductor Cu₂ZnSn(S,Se)₄ or Cu(In,Ga,Al)(S,Se)₂ and preferably of CuInSe₂, CuInS₂, Cu(In,Ga)Se₂ or Cu(In,Ga)(S,Se)₂. In particular, the absorber layer includes Cu(In,Ga)(S,Se)₂ with a ratio of the mole fractions of [S]/([Se]+[S]) on the surface of the absorber layer between 10% and 90%, in particular 20% to 65%, and preferably 35%, by means of which the sulfur is incorporated into the anion lattice of the chalcopyrite structure. By this means, a fine tuning of the band gap and the band adaptation compared to the indium sulfide of the buffer layer can be achieved and particularly high efficiencies can thus be obtained.

The enrichment of the buffer layer takes place by means of a halogen, a halide, or a halogen compound. The halogen is preferably chlorine, bromine, or iodine. The enrichment takes place preferably by means of deposition of one or a plurality of metal-halide compounds of the group metal-chloride, metal-bromide, or metal-iodide. The use of metal-fluoride compounds is also possible, whereby these diffuse very readily out of the enrichment zone due to their low mass and their small atomic radius.

The metal of the metal-halide compound is advantageously an alkali metal, preferably sodium or potassium, an element from the group Ina, preferably indium or a transition element of the group IIb, preferably zinc. Preferred metal-halide compounds are, accordingly, sodium chloride, sodium bromide, sodium iodide, zinc chloride, zinc bromide, zinc iodide, indium chloride, indium bromide, indium iodide, potassium chloride, potassium bromide, and potassium iodide.

Sodium is present in absorber layers made of chalcogenide compound semiconductors either through diffusion from a soda lime glass substrate or by selective addition. The enrichment of alkali metals and, in particular, sodium at the interface can be another advantage of the use of sodium chloride. Sodium thus suppresses the inward diffusion of copper into the indium sulfide buffer layer, which would reduce the band gap in the buffer layer.

In addition to the sodium compounds, the use of indium-halide compounds and, in particular, of indium chloride is particularly advantageous, since indium is a component of the buffer layer and thus no foreign metal is introduced into the layer structure according to the invention.

As experiments of the inventors demonstrated, higher concentrations of oxygen or hydrogen are undesirable as they negatively affect moisture stability of the solar cells. In a first layer region according to the invention, the local mole fraction of the halogen is preferably at least double the local mole fraction of oxygen and/or carbon. In this context, “local” means at any point of the first layer region in a measurement volume obtainable with a measurement method.

In an advantageous embodiment of a layer system according to the invention, the amount of the halogen in the first layer region corresponds to an area concentration of 1·10¹³ atoms/cm² to 1·10¹⁷ atoms/cm² and preferably of 2·10¹⁴ atoms/cm² to 2·10¹⁶ atoms/cm². Here, as well, the expression “amount” includes the amount of the halogen atoms and ions of the halogen element of all oxidation states present. For an area concentration in the preferred range, particularly high efficiencies were measured.

In another advantageous embodiment of a layer system according to the invention, the halogen mole fraction in the buffer layer has a gradient that decreases from the surface facing the absorber layer to the interior of the buffer layer. Through the continuous decrease in the halogen fraction, a particularly advantageous transition between the band structures of the first and second layer regions of the buffer layer develops.

The layer thickness d of a buffer layer according to the invention is preferably from 5 nm to 150 nm and particularly preferably from 15 nm to 50 nm Particularly high efficiencies were obtained for these layer thicknesses.

In an advantageous embodiment of the layer system according to the invention, only the local mole fractions of indium, sulfur, sodium, zinc, and the metal of the metal-halide compound are greater than the local mole fraction of the halogen. Preferably, the buffer layer contains no impurities, in other words, it is not intentionally provided with other elements, such as oxygen or carbon, and includes these, at most, within the limits of concentrations of less than or equal to 5 Mol % unavoidable from a production technology standpoint. This makes it possible to guarantee high efficiency.

Another aspect of the invention comprises solar cells and, in particular, thin-film solar cells with the layer system according to the invention and solar cell modules that include these solar cells.

A solar cell according to the invention comprises at least:
a substrate,
a rear electrode that is arranged on the substrate,
a layer system according to the invention that is arranged on the rear electrode, and
a front electrode that is arranged on the second buffer layer.

The substrate is preferably a metal, glass, plastic, or ceramic substrate, with glass being preferable. Other transparent carrier materials, in particular plastics can be used.

The rear electrode advantageously includes molybdenum (Mo) or other metals. In an advantageous embodiment of the rear electrode, it has a molybdenum sublayer adjoining the absorber layer and a silicon nitride sublayer (SiN) adjoining the molybdenum sublayer. Such rear electrodes are known, for example, from EP 1356528 A1.

The solar cell according to the invention advantageously includes a front electrode made of a transparent conductive oxide (TCO), preferably indium tin oxide (ITO) and/or zinc oxide (ZnO), with doped ZnO, in particular Al-doped ZnO or Ga-doped ZnO particularly preferable.

In an advantageous embodiment of a solar cell according to the invention, a second buffer layer is arranged between the layer system and the front electrode. The second buffer layer preferably includes non-doped zinc oxide and/or non-doped zinc magnesium oxide.

The solar cells produced with this layer system have high efficiencies with, at the same time, high long-term stability. Since, now, no toxic substances are used, the production method is more environmentally safe and less expensive and there are also no follow-up costs, as with CdS buffer layers.

The invention further includes a method for producing a layer system according to the invention, wherein at least

a) an absorber layer that includes a chalcogenide compound semiconductor is prepared and
b) a buffer layer that contains halogen-enriched InₓS_{y} with ⅔≦x/y≦1 is arranged on the absorber layer,
wherein the buffer layer consists of a first layer region adjoining the absorber layer with a halogen mole fraction A₁ and a second layer region adjoining the first layer region with a halogen mole fraction A₂ and the ratio A₁/A₂ is ≧2.

Expediently, the absorber layer is applied in an RTP (“rapid thermal processing”) process on the rear electrode on a substrate. For Cu(In,Ga)(S,Se)₂ absorber layers, a precursor layer is first deposited on the substrate with the rear electrode. The precursor layer includes the elements copper, indium, and gallium, which are applied, for example, by sputtering. At the time of the coating with the precursor layers, a specific sodium dose is introduced into the precursor layers, as is known, for example, from EP 715 358 B1. In addition, the precursor layer contains elemental selenium that is applied by thermal deposition. During these processes, the substrate temperature is below 100° C. such that the elements substantially remain unreacted as metal alloys and elemental selenium. Then, this precursor layer is reacted by rapid thermal processing (RTP) in a sulfur-containing atmosphere to form a Cu(In,Ga)(S,Se)₂ chalcopyrite semiconductor.

In principle, for the production of the buffer layer, all chemical-physical deposition methods in which the molar ratio of halogen or halide to indium sulfide as well as the ratio of indium to sulfur can be controlled in the desired range are suitable.

The buffer layer according to the invention is advantageously applied on the absorber layer by atomic layer deposition (ALD), ion layer gas deposition (ILGAR), spray pyrolysis, chemical vapor deposition (CVD), or physical vapor deposition (PVD). The buffer layer according to the invention is preferably deposited by sputtering, thermal deposition, or electron beam deposition, particularly preferably from separate sources for the halogen and indium sulfide. Indium sulfide can be evaporated either from separate sources for indium and sulfur or from one source with an In₂S₃ compound semiconductor material. Other indium sulfides (In₅S₆/S₇ or InS) are also possible in combination with a sulfur source.

The halogen is preferably introduced from a metal-halogen compound and particularly preferably from a metal-halide compound. Particularly suitable metal halide compounds are sodium chloride, sodium bromide, sodium iodide, zinc chloride, zinc bromide, zinc iodide, indium chloride, indium bromide, indium iodide, potassium chloride, potassium bromide, and/or potassium iodide. These metal-halide compounds are particularly advantageous since they have only slight toxicity, good processability, and simple integratability into existing technical processes. The halogen element chlorine is preferred since the greatest increases in efficiency were evidenced in the experiment.

For the deposition of a metal-halide compound and, in particular, of sodium chloride before the coating with indium sulfide, both wet-chemical and dry processes based on vacuum technology can be used.

In particular, dip coating, spraying, aerosol spraying, pouring, immersion, or washing the absorber layer with a metal-halide-containing solution (for example, with water as solvent) can be used as wet-chemical methods for deposition of a metal-halide compound. The drying of the absorber layer after deposition can take place either at room temperature or at elevated temperatures. If need be, the drying can be assisted by blowing with gaseous nitrogen using a so-called air knife such that a homogeneous metal-halide layer develops on the absorber layer.

The ion layer gas deposition (ILGAR) method is also suitable if, in the case of multiple cycles, the chloride fraction is set higher in the first cycle with the indium and halogen containing precursor, such as indium chloride, than in the following cycles.

The buffer layer according to the invention is advantageously deposited with a vacuum method. The vacuum method has the particular advantage that, under a vacuum, the incorporation of oxygen or hydroxide is prevented. Hydroxide components in the buffer layer are believed to be responsible for transients in efficiency under the effect of heat and light. Moreover, the vacuum methods have the advantage that the method does without wet chemistry and standard vacuum coating equipment can be used.

A further advantage of the vacuum process consists in that a higher material yield can be obtained. Moreover, in contrast to wet deposition, vacuum processes are more environmentally safe since, for example, in contrast to chemical bath deposition, no contaminated wastewater is generated. In addition, different vacuum processes, such as even the production of the second non-doped ZnO buffer layer or the doped ZnO front electrode can be linked in one system, by means of which production can be more economical. Depending on the design of the process for production of the absorber layer, even a combination of the production of the absorber layer and the buffer layer without interim exposure to air is conceivable.

Thermal deposition under a vacuum has the advantage that the method does without wet chemistry and standard vacuum coating equipment can be used. During thermal deposition, the metal-halogen compound is applied directly on the absorber layer in a vacuum environment and the absorber layer with the metal-halogen layer can then be vaporized with indium sulfide without interrupting the vacuum.

In a particularly advantageous embodiment of the method according to the invention, the metal-halogen compound is evaporated from one source and indium sulfide from a separate, second source. The arrangement of the deposition sources is preferably implemented such that the steam beams of the sources overlap completely, partially, or not at all. “Steam beam” in the context of the present application means the region in front of the outlet of the source that is technically suitable for the deposition of the evaporated material on a substrate in terms of deposition rate and homogeneity.

The halogen source, and/or the indium sulfide source are, for example, effusion cells, out of which a metal-halogen compound such as sodium chloride, zinc chloride, or indium chloride or indium sulfide is thermally evaporated. Alternatively, any other form of generation of steam beams is suitable for the deposition of the buffer layer, so long as the ratio of the mole fractions of chlorine, indium, and sulfur can be controlled. Alternative sources are, for example, boats of linear evaporators or crucibles of electron beam evaporators.

In an exemplary embodiment of the method according to the invention, the absorber layer is conveyed past steam beams of sodium chloride and steam beams of indium sulfide or indium and sulfur in an in-line method. The steam beams preferably overlap completely, partially, or not at all. In addition, the deposition rate of the individual sources can be controlled by apertures or by the temperature. A halogen gradient can thus be adjusted by the evaporation geometry and the adjustment of the rates alone.

In an alternative embodiment of the method according to the invention, in the second step b) a metal-halide compound is first deposited on the absorber layer. For example, sodium chloride is evaporated out of an effusion cell. The amount of sodium chloride evaporated is controlled by opening and closing an aperture or by temperature control. Then, in a further step, a buffer layer of indium sulfide is deposited, preferably without vacuum interruption, on the absorber layer coated with the metal-halide compound.

In an alternative embodiment of the in-line method according to the invention for producing a buffer layer according to the invention, the halogen source and the indium sulfide source are arranged one after another such that their steam beams overlap at least partially, preferably from 10% to 70% and particularly preferably from 25% to 50%. In this manner, a gradient with a continuous decrease in the halogen concentration can be formed in the buffer layer, which is particularly advantageous for the properties of the solar cell according to the invention.

A further aspect of the invention comprises a device for production of a buffer layer according to the invention in an in-line method, wherein at least one halogen source and at least one indium sulfide source are arranged one after another such that their steam beams overlap at least partially, preferably from 10% to 70% and particularly preferably from 25% to 50%.

The invention is explained in detail in the following with reference to drawings and an example. The drawings are not completely true to scale. The invention is in no way restricted by the drawings. They depict:

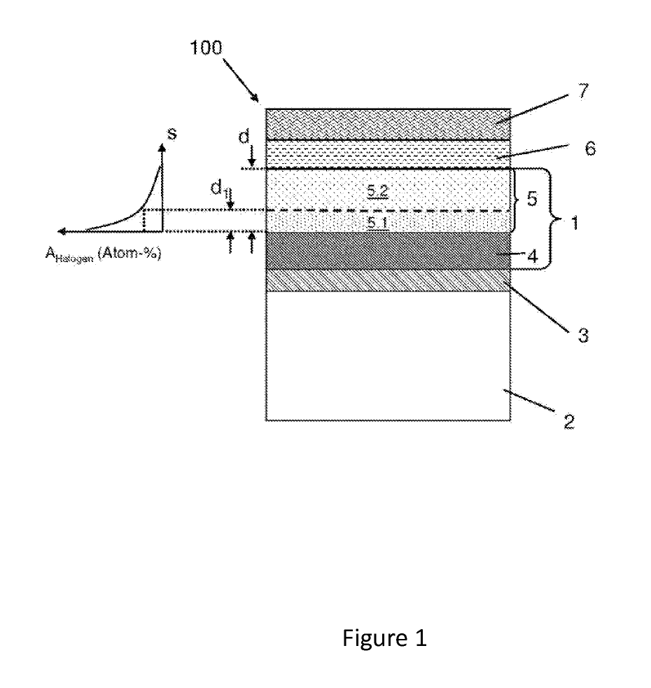

FIG. 1 a schematic cross-sectional view of a thin-film solar cell with a layer system according to the invention,

FIG. 2 a diagram of the depth profile of the chlorine content of a layer structure according to the invention with a comparative example,

FIG. 3 a diagram of the depth profile of the chlorine, copper, indium, sulfur, and selenium content of a layer structure according to the invention,

FIG. 4 a diagram of the photoluminescence lifetime of a layer structure according to the invention with a comparative example,

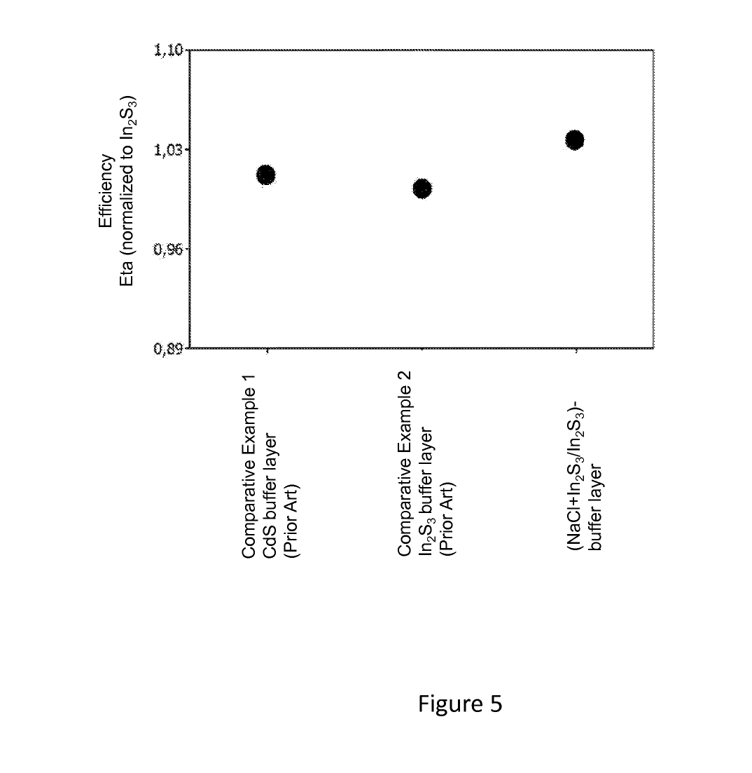

FIG. 5 a diagram of the efficiency of a thin-film solar cell according to the invention with a comparative example,

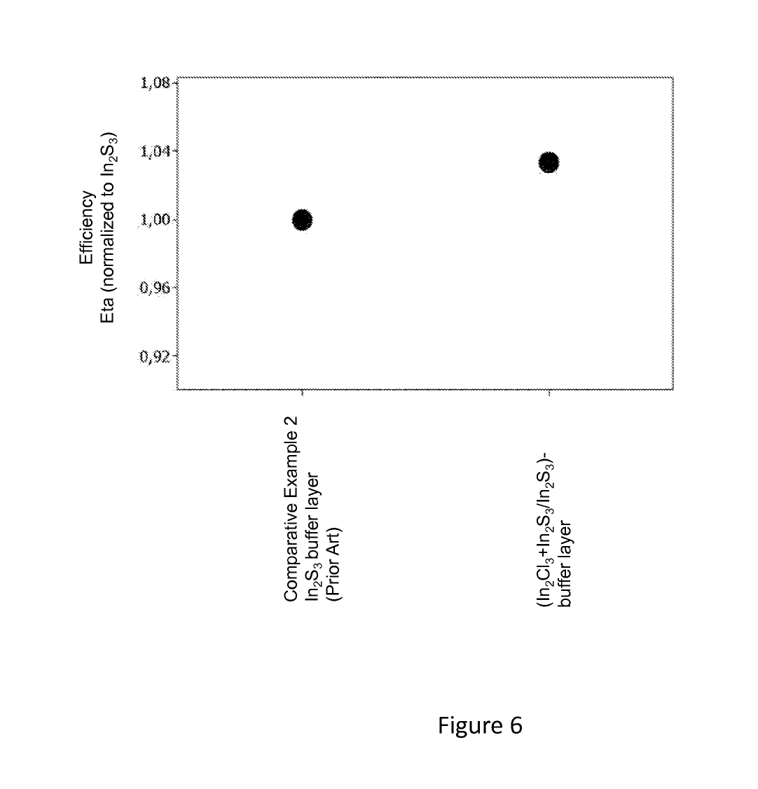

FIG. 6 a diagram of the efficiency of another thin-film solar cell according to the invention with a comparative example,

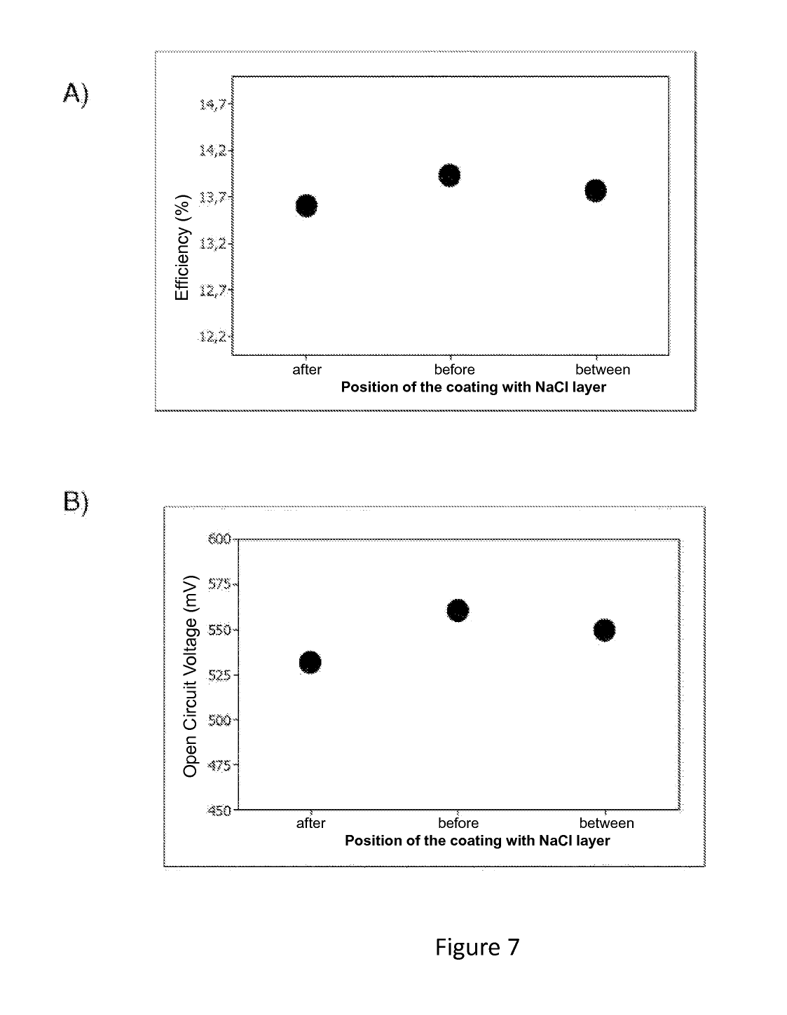

FIG. 7 A a diagram of the efficiency of a thin-film solar cell according to the invention with a comparative example,

FIG. 7 B a diagram of the open circuit voltage of a thin-film solar cell according to the invention with a comparative example,

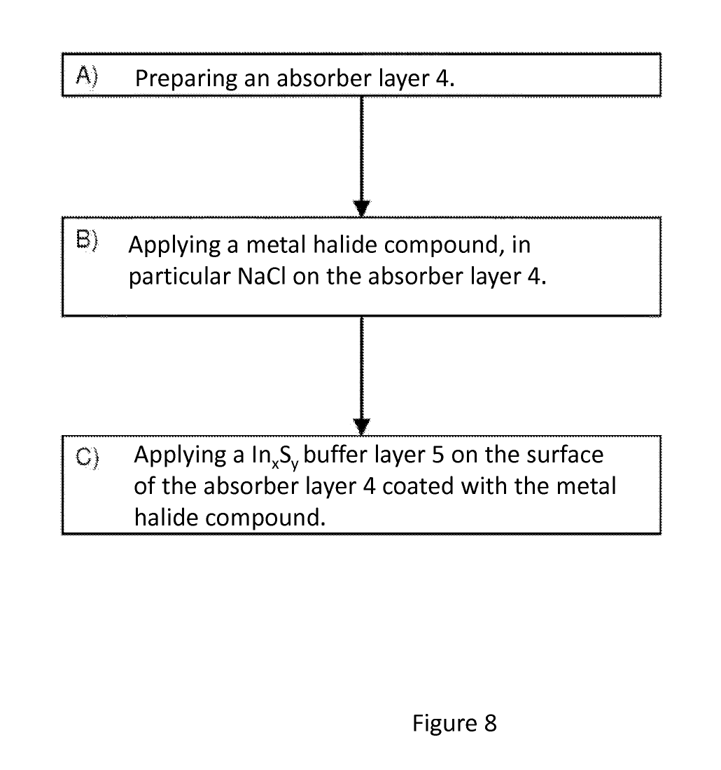

FIG. 8 an exemplary embodiment of the process steps according to the invention with reference to a flow diagram,

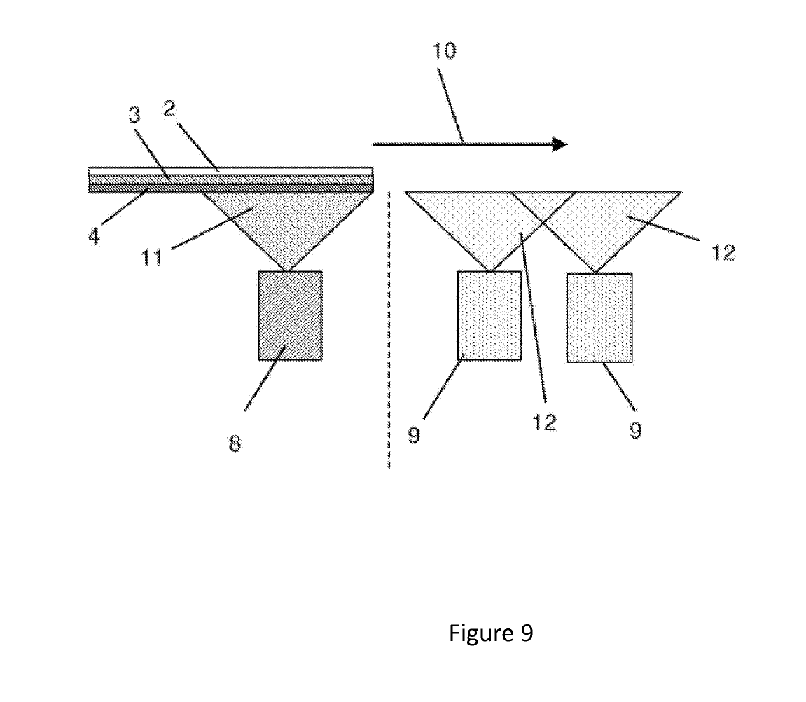

FIG. 9 a schematic depiction of an in-line method for producing a buffer layer according to the invention,

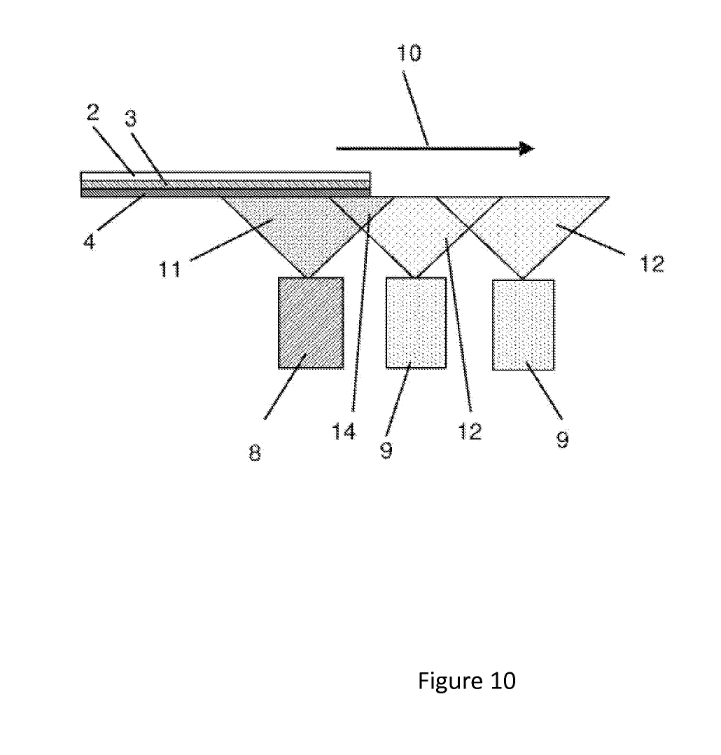

FIG. 10 a schematic depiction of an alternative in-line method for producing a buffer layer according to the invention.

FIG. 1 depicts purely schematically a preferred exemplary embodiment of a thin-film solar cell 100 according to the invention with a layer system 1 according to the invention in a cross-sectional view. The thin-film solar cell 100 includes a substrate 2 and a rear electrode 3. A layer system 1 according to the invention is arranged on the rear electrode 3. The layer system 1 according to the invention comprises an absorber layer 4 and a buffer layer 5. A second buffer layer 6 and a front electrode 7 are arranged on the layer system 1.

The substrate 2 is made here, for example, of inorganic glass, with it equally possible to use other insulating materials with sufficient stability as well as inert behavior relative to the process steps performed during production of the thin-film solar cell 100. Depending on the layer thickness and the specific material properties, the substrate 2 can be implemented as a rigid plate or flexible film. In the present exemplary embodiment, the layer thickness of the substrate 2 is, for example, from 1 mm to 5 mm.

A rear electrode 3 is arranged on the light-entry side surface of the substrate 2. The rear electrode 3 is made, for example, from an opaque metal. It can, for example, be deposited on the substrate 2 by vapor deposition or magnetic field-assisted cathode sputtering. The rear electrode 3 is made, for example, of molybdenum (Mo), aluminum (Al), copper (Cu), titanium (Ti), or of a multilayer system with such a metal, for example, molybdenum (Mo). The layer thickness of the rear electrode 3 is, in this case, less than 1 μm, preferably in the range from 300 nm to 600 nm, and is, for example, roughly 500 nm. The rear electrode 3 serves as a back-side contact of the thin-film solar cell 100. An alkali barrier, made, for example, of Si₃N₄, SiON, or SiCN, can be arranged between the substrate 2 and the rear electrode 3. This is not shown in detail in FIG. 1.

A layer system 1 according to the invention is arranged on the rear electrode 3. The layer system 1 includes an absorber layer 4, made, for example, of Cu(In,Ga)(S,Se)₂, which is applied directly on the rear electrode 3. The absorber layer 4 has, for example, a thickness of 1.5 μm.

A buffer layer 5 is arranged on the absorber layer 4. The buffer layer 5 includes InₓS_{y} with ⅔≦x/y≦1 and, for example, In₂S_{2.8}. The layer thickness d of the buffer layer 5 is from 5 nm to 150 nm and, for example, 35 nm. The buffer layer 5 consists of a first layer region 5.1 that adjoins the absorber layer 4 and is connected over its entire area to the absorber layer 4. Moreover, the buffer layer 5 includes a second layer region 5.2, which is arranged on the first layer region 5.1. The first layer region has a thickness d₁ that is less than 50% of the layer thickness d of the entire buffer layer 5. The thickness d₁ of the first layer region 5.1 is, for example, 10 nm. The first layer region 5.1 contains a halogen mole fraction A₁ and the second layer region 5.2, a halogen mole fraction A₂. The ratio of the halogen mole fractions A₁/A₂ is ≧2 and, for example, 10. For clarification, an exemplary curve of the halogen mole fraction A_{Halogen} is depicted in FIG. 1 as a function of the layer depth s. The data of the halogen mole fraction A_{Halogen} are plotted in atom-%, with the halogen mole fraction also including halogen ions and halogen in compounds.

A second buffer layer 6 can be arranged above the buffer layer 5. The buffer layer 6 includes, for example, non-doped zinc oxide. A front electrode 7 that serves as a front-side contact and is transparent to radiation in the visible spectral range (“window layer”) is arranged above the second buffer layer 6. Usually, a doped metal oxide (TCO=transparent conductive oxide), for example, n-conductive, aluminum (Al)-doped zinc oxide (ZnO), boron (B)-doped zinc oxide (ZnO), or gallium (Ga)-doped zinc oxide, is used for the front electrode 7. The layer thickness of the front electrode 7 is, for example, roughly 300 to 1500 nm. For protection against environmental influences, a plastic layer (encapsulation film) made, for example, of polyvinyl butyral (PVB), ethylene vinyl acetate (EVA), or DNP can be applied to the front electrode 7. In addition, a cover plate transparent to sunlight that is made, for example, from extra white glass (front glass) with a low iron content and has a thickness of, for example, 1 to 4 mm, can be provided.

The described structure of a thin-film solar cell or a thin-film solar module is well known to the person skilled in the art, for example, from commercially available thin-film solar cells or thin-film solar modules and has also already been described in detail in numerous printed documents in the patent literature, for example, DE 19956735 B4.

In the substrate configuration depicted in FIG. 1, the back electrode 3 adjoins the substrate 2. It is understood that the layer structure 1 can also have a superstrate configuration, in which the substrate 2 is transparent and the front electrode 7 is arranged on a surface of the substrate 2 facing away from the light-entry side.

The layer structure 1 can serve for production of integrated serially connected thin-film solar cells, with the layer structure 1, the front electrode 7, the rear electrode 3, and the front electrode 7 patterned in a manner known per se by various patterning lines (“P1” for rear electrode, “P2” for front electrode/back electrode contact, and “P3” for separation of the front electrode).

The best efficiency to date was obtained with a thin-film solar cell 100 according to FIG. 1. The substrate 1 contained glass with a Si₃N₄-barrier layer and a molybdenum rear electrode 2. A Cu(In,Ga)(S,Se)₂-absorber layer 4 that had been produced according to the above-described RTP process was arranged on the rear electrode. A buffer layer 5 was arranged on the absorber layer 4. The buffer layer 5 contained InₓS_{y} with a ratio x/y of the amounts of substance of indium to sulfur of 42/58. The thickness d of the buffer layer 5 was 35 nm. The buffer layer 5 included a first layer region 5.1 with a thickness d₁ of 10 nm. The chlorine content of the first layer region 5.1 corresponded to an area concentration of 1×10¹⁵ chlorine atoms/cm². The chlorine enrichment took place by means of a coating of the absorber layer 4 before the deposition of the indium sulfide layer. A second buffer layer made of non-doped zinc oxide with a layer thickness of roughly 90 nm was arranged on the buffer layer 5. A front electrode made of n-conductive zinc oxide with a layer thickness of 1200 nm was arranged on the second buffer layer 6. The photoactive area of the thin-film solar cell 100 was 1.4 cm². The efficiency was 15.2%. The characteristic data indicated a high open circuit voltage V_{∞} of 582 mV and a good filling factor FF of 70.8%.

Good efficiencies were also obtained with the metal halide potassium chloride (KCl): in this case, potassium chloride was thermally deposited such that the chlorine amount on the absorber layer 4 was roughly the same as with the above-described cell with sodium chloride. Then, without vacuum interruption, indium sulfide was deposited. After production of the thin-film solar cell 100 analogous to the preceding example, it was already possible in the initial tests to obtain an efficiency of 14.6%.

FIG. 2 depicts the depth profile of the chlorine fraction measured by high-resolution time-of-flight secondary ion mass spectrometry (ToF-SIMS) of three differently prepared buffer layers 5 on an absorber layer 4. The chlorine fraction describes the fraction of all chlorine atoms present in the buffer layer 5 regardless of their oxidation state.

The reference measurement was made using a comparative example on an indium sulfide buffer layer according to the prior art without a first layer region 5.1 with halogen enrichment according to the invention. In the cases Cl-amount 1 and Cl-amount 2, two different amounts of sodium chloride were applied according to the invention on the absorber layer 4 before the actual deposition of the buffer layer 5 made of indium sulfide. The chlorine area concentration of Cl-amount 1 was roughly 2×10¹⁴ Cl-atoms/cm². The chlorine area concentration of Cl-amount 2 was roughly 3×10¹⁴ Cl-atoms/cm² and resulted in 1.5 times the chlorine amount on the absorber layer 4.

In FIG. 2, the normalized sputtering time is plotted on the x-axis. The sputtering time corresponds to the sputter depth with the analysis beginning on the surface of the buffer layer 5 facing away from the absorber layer 4. The buffer layer 5 corresponds to the region 0 to 1 on the x-axis and the absorber layer 4 corresponds to the region with values >1. FIG. 2 shows that after somewhat more than half of the buffer layer with a normalized sputtering time of 0.6, a chlorine signal rises in a delta shape and drops again to lower values on obtaining the absorber layer 4 at a normalized sputtering time of roughly 1. The intensities outside the maximum are attributable in part to diffusion and in part to smearing of the profile due to the relatively rough surface topography of the absorber layer 4. The comparative example also shows smaller amounts of chlorine with normalized sputtering times between 0.6 and 0.8, which are attributable to impurities in the starting materials for the deposition. However, the low coating thickness of chlorine in the comparative example is insufficient to exert a noteworthy positive effect on efficiency.

FIG. 3 additionally depicts the depth profile of the chlorine enrichment with regard to the interface of absorber layer 4 and buffer layer 5 using Example Cl-amount 1 from FIG. 2 with the other elements copper, indium, sulfur, and selenium. As anticipated, in the region of the indium sulfide buffer layer 5, large fractions of sulfur and indium were measured and in the region of the absorber layer 4, large fractions of copper, selenium, indium, and a smaller fraction of sulfur. It was shown, in particular, that the intensity of the copper signal drops sharply from the interface between absorber layer 4 and buffer layer 5 in the direction of buffer layer 5 and overlaps only a little with the region of high chlorine intensities.

The present invention is based on the finding of the inventors that the relatively large halogen atoms or halogen ions localized at the interface reduce, as a diffusion barrier, the inward diffusion of impurities such as copper out of the absorber layer 4 into the buffer layer 5. The halogen atoms or halogen ions localized at the interface in the first layer region 5.1 alter the electronic properties of the buffer layer 5 itself in a positive manner. An inward diffusion of copper into In₂S₃ buffer layers is described, for example, in Barreau et al, Solar Energy 83, 363, 2009 and leads, via a reduction of the band gap, to increased optical losses. This occurs primarily through a shift of the valence band maximum, which could, in turn, have a disrupting effect on the formation of the energetically optimum band structure at the p-n-junction. Furthermore, halogen enrichment according to the invention at the interface between the absorber layer 4 and the buffer layer 5 can electronically mask and neutralize defects possibly occurring such that these are no longer active as recombination centers and, thus increase the efficiency of the thin-film solar cell 100 overall. In order to detect the reduction of recombination centers, measurements of the photoluminescence lifetime were performed with different buffer layers on absorber/buffer heterojunctions.

FIG. 4 depicts a diagram of the photoluminescence lifetime for various buffer layers 5. The lifetime was measured with a photoluminescence measuring station and a 633 nm-laser. Here, the typical penetration depth of the laser light is roughly 70 nm. This means that the photoluminescence of the surface and the region near the surface (in particular the space charge zone at the pn-junction) is measured. The photoluminescence decay time measured corresponds to an effective lifetime that is determined both by the recombination of the charge carriers in the volume and by the recombination at the interface to the buffer layer 5. FIG. 4 presents the typical lifetime of pn-junctions of a buffer layer 5 according to the invention made of indium sulfide with chloride enrichment and two comparative examples according to the prior art.

Comparative example 1 is a CdS buffer layer according to the prior art. The good lifetime of roughly 40 ns in pn-junctions with CdS buffer layers can be attributed to the very good reduction of interface defects due to the wet chemical processing. Comparative example 2 is a buffer layer according to the prior art made of indium sulfide without halogen enrichment. The pure In₂S₃ buffer layer results in a clear reduction of the lifetime to roughly 10 ns, which is attributable to an increased recombination of the charge carriers on the surface and in layers near the surface.

The example shows a NaCl+In₂S₃/In₂S₃ buffer layer 5 according to the invention, wherein, before deposition of the buffer layer 5, sodium chloride was applied on the absorber layer 4. This results in the formation of a first layer region 5.1 according to the invention with an increased halogen mole fraction A₁. The buffer layer 5 according to the invention presents a significantly increased lifetime of roughly 41 ns. The lifetime in the buffer layer 5 according to the invention falls within the range of the lifetime of Comparative Example 1, a CdS buffer layer. It can be concluded that despite the dry method of deposition of the buffer layer 5 according to the invention, a significant reduction of interface defects is achieved. The introduction of the halogen-rich interface thus actually results in an improvement of the electronic properties of the absorber-buffer interface, in comparison to an indium sulfide buffer layer without halogen enrichment.

The efficiency of buffer layers 5 according to the invention with halide enrichment at the interface to the absorber layer 4 is improved relative to pure indium sulfide buffer layers over a wide range relative to the halogen mole fraction A₁ in the first layer region 5.1.

FIG. 5 depicts the efficiency of thin-film solar cells 100 with a buffer layer 5 according to the invention with a NaCl pre-coating and two comparative examples according to the prior art. In Comparative Example 1, the buffer layer is a wet-chemically deposited CdS layer. In Comparative Example 2, the buffer layer is an indium sulfide layer without halogen enrichment deposited from the gas phase. The buffer layer 5 according to the invention was produced by a NaCl pre-coating by pre-deposition of sodium chloride onto the absorber layer 4. Then, indium sulfide was deposited from the gas phase onto the NaCl pre-coating. As can be discerned from FIG. 5 the highest efficiencies, averaging 1.04 normalized to the efficiency of Comparative Example 2, i.e., an In₂S₃ buffer layer according to the prior art without halogen enrichment, are obtained with the buffer layer 5 according to the invention with NaCl pre-coating.

FIG. 6 presents the measurement of the efficiency for an In₂S₃ buffer layer according to the prior art without InCl₃ pre-coating compared to the efficiency of an alternative buffer layer 5 according to the invention with halogen enrichment through pre-coating with indium chloride (InCl₃). InCl₃ pre-coating also results in halogen enrichment in the first layer region 5.1 at the interface to the absorber layer 4, which dopes the interface and, moreover, reduces the surface defects. FIG. 6 clearly shows that halogen enrichment of the buffer layer 5 according to the invention increases the efficiency of thin-film solar cells 100. The increase in efficiency with InCl₃ pre-coating is, in this case, roughly 4% and is in the same order of magnitude as with a NaCl pre-coating in FIG. 5.

Copper, oxygen, and selenium can also be found in the buffer layer 5 in addition to the elements indium, sulfur, and chlorine. Indium sulfide has a relatively open lattice structure into which other elements such as sodium and copper can be incorporated quite well. The deposition of the buffer layer 5 can occur at relatively high temperatures, in particular at temperatures from room temperature to roughly 200° C. The subsequent transparent front electrode 7 is also deposited preferably at temperatures up to 200° C. At these temperatures, sodium, copper, and selenium can diffuse out of the absorber layer 4 or the front electrode 7 into the buffer layer 5. In this case, these elements can also be enriched at the interface through pre-coating with a metal-halogen compound in addition to halogen. Depending on the selection of the metal-halogen compound, the accompanying metal in the first layer region 5.1 of the buffer layer 5 will also be enriched. Due to the hygroscopic properties of the starting materials, enrichment by water from the ambient air is also conceivable.

FIG. 7 A depicts the efficiency and FIG. 7 B the open circuit voltage as a function of the distribution of NaCl enrichment according to the invention in the buffer layer 5. Thin-film solar cells 100 with layer systems 1, wherein sodium chloride was applied after deposition of the buffer layer (“after”), before deposition of the buffer layer (“before”), and within the buffer layer 5 (“between”), are compared. The thin-film solar cell 100 corresponds to the arrangement as it was described under FIG. 1. The layer system 1 “before”, wherein sodium chloride was deposited before the deposition of the buffer layer 5, presents the highest efficiency, averaging 14%, and the highest average open circuit voltage of 560 mV. FIG. 7 A and FIG. 7 B document the particular effectiveness of halogen enrichment in a first layer region 5.1 at the interface to the absorber layer 4 through pre-coating of the absorber layer 4 with sodium chloride (“before”) in contrast to positioning in the middle of the buffer layer 5 (“between”) or post-coating (“after”) at the interface to the second buffer layer 6.

FIG. 8 depicts a flow diagram of a method according to the invention. In a first step, an absorber layer 4 is prepared, for example, from a Cu(In,Ga)(S,Se)₂ semiconductor material. In a second step, a metal halide layer, made, for example, of sodium chloride is applied, and in another step, the buffer layer of indium sulfide is deposited. As explained below, indium sulfide can also be deposited already in the second step in addition to the metal halide. The ratio of the individual components in the buffer layer 5 is regulated, for example, by control of the deposition rate, for example, by an aperture or by temperature control.

In further process steps, a second buffer layer 6 and a front electrode 7 can be deposited on the buffer layer 5. In addition, connecting and contacting of the layer structure 1 to a thin-film solar cell 100 or to a solar module can take place.

FIG. 9 presents a schematic depiction of an in-line method for producing a buffer layer 5 according to the invention. In an in-line method, the substrate 2 with rear electrode 3 and absorber layer 4 is conveyed past the steam beam 11 of a halogen-containing evaporator source and, for example, past a sodium chloride source 8. The transport direction is indicated by an arrow with the reference character 10.

The amount of sodium chloride deposited is adjusted, for example, by opening and closing an aperture such that an NaCl amount of more than 1×10¹³ atoms/cm² and less than 1×10¹⁷ atoms/cm² is deposited on the surface.

Then, the absorber layer 4 pre-coated with sodium chloride is conveyed past at least one indium sulfide source 9. This occurs preferably without vacuum interruption. The layer thickness d of the buffer layer 5 and the halogen enrichment profile over the buffer layer 5 can be controlled by the deposition rate, transport speed, and number of halogen and indium sulfide sources 8,9.

The source for the deposition of the metal-halogen compound as well as of indium sulfide or of indium and sulfur is, for example, an effusion cell, a boat or crucible of a thermal evaporator, of a resistance heater, of an electron beam evaporator, or of a linear evaporator.

FIG. 10 presents a schematic depiction of an alternative in-line method for producing a buffer layer 5 according to the invention. The sodium chloride source 8 and the indium sulfide source 9 are arranged one after another such that the steam beam 11 of the sodium chloride sources 8 and the steam beam 12 of the indium sulfide source 9 overlap in an overlap region 14. The sodium chloride source 8 and the indium sulfide source 9 are, for example, effusion cells out of which sodium chloride or indium sulfide is thermally evaporated. Alternatively, any other form of generation of steam beams 11,12 is suitable for the deposition of the buffer layer 5 so long as the ratio of the mole fractions of chlorine, indium, and sulfur can be controlled. The vaporization of the buffer layer can, for example, take place in an additional sulfur atmosphere.

In this manner, for example, a gradient with a continuous decrease in halogen concentration can be formed in the buffer layer 5. As experiments of the inventors have demonstrated, such a gradient is particularly advantageous for the electronic and optical properties of the thin-film solar cell 100 according to the invention.

The introduction of sodium and chlorine from sodium chloride into the indium sulfide buffer layer 5 has multiple special advantages. Sodium chloride is non-toxic and economical and can, as already mentioned, be readily applied using thermal methods. During thermal deposition, sodium chloride evaporates as NaCl molecules and does not dissociate to sodium and chlorine. This has the particular advantage that during evaporation, no toxic and corrosive chlorine develops.

The introduction of sodium and chlorine from sodium chloride offers additional advantages from a production technology standpoint. Only one substance has to be evaporated, greatly simplifying the process compared to possible mixtures of substances such as NaCl/In₂S₃. Furthermore, the vapor pressure curve of sodium chloride is known, for example, from C. T. Ewing, K. H. Stern, “Equilibrium Vaporization Rates and Vapor Pressures of Solid and Liquid Sodium Chloride, Potassium Chloride, Potassium Bromide, Cesium Iodide, and Lithium Fluoride”, J. Phys. Chem., 1974, 78, 20, 1998-2005, and a thermal vapor deposition process can be readily controlled by temperature. Moreover, an arrangement for vapor deposition of sodium chloride can be readily integrated into existing thermal indium sulfide coating equipment.

Moreover, halide enrichment can be controlled and measured simply. Thus, for process control during the vapor deposition, a quartz resonator can be used for direct measurement of the rate. An optical control of the sodium amount and, consequently, the chloride amount can be used by means of emission spectroscopy. Alternatively, sodium chloride can be deposited on silicon and this can be investigated with x-ray fluorescence analysis (XRF), with an ellipsometer or a photospectrometer in-line or after the process.

From the above assertions, it has become clear that by means of the present invention the disadvantages of previously used CdS buffer layers or the alternative buffer layers were overcome in thin-film solar cells, with the efficiency and the stability of the solar cells produced therewith also very good or better. At the same time, the production method is economical, effective, and environmentally safe. This was unexpected and surprising for the person skilled in the art.

### REFERENCE CHARACTERS

1 layer system
2 substrate
3 rear electrode
4 absorber layer
5 buffer layer
5.1 first layer region
5.2 second layer region
6 second buffer layer
7 front electrode
8 sodium chloride source
9 indium sulfide source
10 transport direction
11 sodium chloride steam beam
12 indium sulfide steam beam
14 overlapping region
100 thin-film solar cell, solar cell
d layer thickness of the buffer layer 5
d₁ layer thickness of the first layer region 5.1
s layer depth
A₁ halogen mole fraction in the first layer region 5.1
A₂ halogen mole fraction in the second layer region 5.2
A_{Halogen} halogen mole fraction

1. Layer system for thin-film solar cells, comprising:
an absorber layer that includes a chalcogenide compound semiconductor and
a buffer layer that is arranged on the absorber layer and includes halogen-enriched InₓS_{y} with ⅔≦x/y≦1,
wherein the buffer layer consists of a first layer region adjoining the absorber layer with a halogen mole fraction A₁ and a second layer region adjoining the first layer region with a halogen mole fraction A₂ and the ratio A₁/A₂ is ≧2 and the layer thickness of the first layer region is ≦50% of the layer thickness of the buffer layer.

2. Layer system according to claim 1, wherein the layer thickness of the first layer region is ≦30% of the layer thickness of the buffer layer.

3. Layer system according to claim 1, wherein the ratio A₁/A₂ is from 2 to 1000.

4. Layer system according to claim 1, wherein the amount of the halogen in the first layer region amounts to an area concentration of 1·10¹³ atoms/cm² to 1·10¹⁷ atoms/cm².

5. Layer system according to claim 1, wherein the halogen mole fraction in the buffer layer has a gradient that decreases from the surface facing the absorber layer to the interior of the buffer layer.

6. Layer system according to claim 1, wherein the layer thickness of the buffer layer is from 5 nm to 150 nm.

7. Layer system according to claim 1, wherein the halogen is chlorine, bromine, or iodine.

8. Layer system according to claim 1, wherein the chalcogenide compound semiconductor includes Cu(In,Ga,Al)(S,Se)₂.

9. Layer system according to claim 1, wherein in the first layer region the local mole fraction of the halogen is at least two times the local mole fraction of oxygen and/or carbon.

10. Thin-film solar cell, comprising:
a substrate,
a rear electrode that is arranged on the substrate,
a layer system according to claim 1 that is arranged on the rear electrode, and
a front electrode that is arranged on the layer system.

11. Method for producing a layer system for thin-film solar cells, wherein
a) an absorber layer that contains a chalcogenide compound semiconductor is prepared,
b) a buffer layer that contains halogen-enriched InₓS_{y} with ⅔≦x/y≦1 is arranged on the absorber layer,
wherein the buffer layer consists of a first layer region adjoining the absorber layer with a halogen mole fraction A₁ and a second layer region adjoining the first layer region with a halogen mole fraction A₂ and the ratio A₁/A₂ is ≧2, and the layer thickness of the first layer region is ≦50% of the layer thickness of the buffer layer.

12. Method according to claim 11, wherein in the step b) a metal-halide compound is applied on the absorber layer and InₓS_{y} is applied on the metal-halide compound.

13. Method according to claim 11, wherein in the step b) a metal-halide compound and indium sulfide are applied on the absorber layer.

14. Method according to claim 13, wherein, in an in-line method, the absorber layer is conveyed past at least one steam beam of the metal-halide compound and at least one steam beam of indium sulfide.

15. Method according to claim 12, wherein the metal-halide compound with chlorine, bromine, and/or iodine as halogen and sodium, potassium, aluminum, gallium, indium, zinc, cadmium, and/or mercury as metal are applied.

16. (canceled)

17. Layer system according to claim 1, wherein the layer thickness of the first layer region is ≦20% of the layer thickness of the buffer layer.

18. Layer system according to claim 1, wherein the ratio A₁/A₂ is from 5 to 100.

19. Layer system according to claim 1, wherein the amount of the halogen in the first layer region amounts to an area concentration of 2·10¹⁴ atoms/cm² to 2·10¹⁶ atoms/cm².

20. Layer system according to claim 1, wherein the layer thickness of the buffer layer is from 15 nm to 50 nm.

21. Layer system according to claim 1, wherein the chalcogenide compound semiconductor includes CuInSe₂, CuInS₂, Cu(In,Ga)Se₂, Cu(In,Ga)(S,Se)₂, or Cu₂ZnSn(S,Se)₄.
